(19) United States
(12) Patent Application Publication
(10) Pub. No.: US 2005/0205882 A1
(43) Pub. Date: Sep. 22, 2005

(54) LED-photo-curing device

(76) Inventor: John Condon, Portland, OR (US)

Correspondence Address: JOHN RAYMOND CONDON, 15571 SE OATFIELD RD., PORTLAND, OR, 97267, US

(21) Appl. No.: 10/800,995

(22) Filed: Mar. 16, 2004

(51) Int. Cl. H01L 33/00

(52) U.S. Cl. 257/88

(57) ABSTRACT

A device is described which possesses an array of light-emitting diodes configured to distribute the light energy over the surface of a volume of material. The device is suited to photo-initiating the polymerization of photo-sensitized polymer or polymer composites.

### FEDERAL SPONSORSHIP

This invention was the result of research that was funded by an SBIR grant provided by the National Institutes of Health/National Institute of Dental and Craniofacial Research.

### BACKGROUND

1. Field of the Invention

Photo-initiated free-radical polymer and polymer composites are convenient materials for in situ repair, such as in dentistry, where light-curable polymer-ceramic composites are used as a leading tooth-colored restorative material. These composites are dispensed as pastes and become hard when they are exposed to blue light, which acts to initiate their free-radical polymerization. Filtered blue light from filament bulbs have largely been used as the source of photo-initiating energy. More recently, light-curing devices using blue LEDs have become popular because their frequency closely matches the excitation frequency of the photo-initiating agent used in dental composite, while having less of the infra-red energy that can heat the tooth and damage its pulp. The lower size and energy requirement of the LEDs allow the construction of cordless and more compact designs, and also provide longer bulb life.

Evaluating the mechanical properties of photo-initiated polymers and polymer composites requires that uniform monolithic specimens be prepared. When the handheld light-curing units such as those used in dentistry are employed for making such specimens, typically the specimen dimensions are larger than the output beam of the curing unit, which is typically in the range of 5-10 mm in diameter. This size requires that multiple applications of the light in overlapping spots be performed, which can be very time consuming. The uncertainty in positioning the output tip away from the surface and across the face of the surface for a time period that can also vary introduces much uncertainty in the level of cure that will be achieved throughout the specimen.

2. Prior Art

A number of U.S. Patents have been issued which cover the use of blue LEDs to initiate the polymerization of dental restoratives. U.S. Pat. No. 6,159,005, issued to Herold, describes a device that uses blue LEDs focused on a transmitting tip to conduct the light to the treatment site. U.S. Pat. No. 6,102,695 issued to Ostewalder et al. discloses a portable, light-emitting handpiece for curing photo-polymerizable resins of the type used in dental repair and restoration procedures. In U.S. Pat. No. 5,420,768, issued to Kennedy, another relatively compact and self-contained LED photo-curing device is disclosed. In U.S. Pat. No. 6,200,134, issued to Kovac et al., a light-emitting dental handpiece, somewhat similar to those described above, is disclosed in which the problem of overheating of a relatively small array of LED's is addressed by the provision of a small electric fan mounted in the neck portion of the device. U.S. Pat. No. 6,318,996, issued to Melikechi, describes the curing of a photo-polymer composite dental restoration using a single LED. All of these patents describe systems wherein the light emitted from the diodes is concentrated into a light guide, which issues a single beam to be directed onto the surface of a restoration that is being placed in the mouth of a dental patient. In U.S. Pat. No. 6,331,111, to issued to Cao, a hand-holdable resin-curing light system is disclosed in which the problem of light source overheating is also addressed. While this patent does not include the use of a light guide, the geometry of the array of LEDs is such that a single bright beam of light is generated to be directed a localized body of photo-polymerizable material.

Another important means of photo-initiating polymer composites involves a light box, which can contain several high-intensity halogen light bulbs directed toward a stage, on which is placed laboratory dental prosthetics to be cured, such as crowns, bridges and palettes. In dental materials research, these so called light-curing ovens can be used to simultaneously illuminate the entire specimen, though the intensity they provide can be insufficient to attain complete cure, and their sensitivity to positioning of the specimen within the oven can be a source of variability in the level of cure attained.

For dental materials research, monolithic specimens for mechanical testing of photo-initiated polymer and polymer composites are formed by placing the uncured material in a mold that has a metal frame and two open faces to which Mylar matrix band is applied. These provide a transparent but reasonably flat surface through which the initiating light energy can be directed. Also, glass tubing having precise inner dimensions can be used, in which the polymer or polymer composite is injected into the tube and the initiating light energy is directed through the wall of the glass tube. Polymer composites such as those used in dentistry typically can be effectively cured to a depth of approximately 2.5 mm. A device which illuminates the polymer from opposite sides can therefore effectively cure thicknesses in the range of 5 to 7 mm.

Photo-initiated polymer is also used in a number of electronics manufacturing processes as adhesives, insulators and masks during photolithographic operations. These polymers are often sensitized to ultra-violet light, which is provided through high-voltage lamps. UV-emitting diodes have been developed, but because of their lower power output, they have not been used widely in electronics manufacturing.

### DRAWINGS

FIG. 1 shows an LED-equipped curing device for the preparation of dental prostheses.

### REFERENCE NUMERALS IN DRAWINGS

1 Array of Light-emitting diodes
2 Hinge
3 Platform
4 Container
5 Power cord
6 Intensity control
7 Timer control
8 Power switch

### DESCRIPTION OF THE INVENTION

The device shall consist of an array of light emitting diodes in any available package having their direction of illumination arranged around a boundary having the shape of an object desired to be photo-initiated. A mechanical framework for supporting the LEDs is present, and any members for aligning the object to be photo-initiated with the LEDs. A DC power supply provides current to the LEDs, which are wired either in series or in parallel. The current is moderated by a ballast resister in series with the LEDs.

A device is hereby described wherein an array of light-emitting diodes (LEDs) is arranged so that the light energy is spread evenly over the surface of a volume of material. The device is suited for the photo-initiation of polymer and polymer composites. In one embodiment, the device can accommodate a specimen mold made of square glass tubing into which polymer or polymer composite has been injected. The LEDs are arranged in a cylindrical pattern wherein their illuminating ends are all directed toward the major axis of the tubing. The distance between the LEDs across the major axis should be large enough to allow the glass mold to be inserted. The distance between the LEDs along the major axis should be as small as possible to make the light intensity as high and as even as possible. The distance along the major axis wherein the LEDs are distributed should be long enough to illuminate the entire length of the specimen to be irradiated. The output of the LEDs can vary according to viewing angle. The LEDs should have a wide enough viewing angle so that the output of two LEDs that are adjacent to one another shall overlap enough to provide a sufficiently high level of irradiation energy to reach the specimen.

Sufficient initiating energy must be supplied to photo-sensitized polymers to achieve high levels of conversion. A high spatial density of LEDs and the use of high intensity LEDs in the design can currently provide blue-light illumination in the range of 50-100 mW/cm2. Though halogen and plasma light sources used in dentistry range from 400-1000 mW/cm2 in intensity, the LEDs produce a spectrum that much more closely matches the absorption spectrum of the commonly-used photo-initiating compound camphoroquinone. The DC power could have a voltage regulator to stabilize the intensity supplied by the LEDs. The currently described device can also posses an electric or electronic control of the power supplied to the LEDs, changing their intensity.

The duration of the light exposure effects the degree of polymerization that occurs. The currently described device can have an electric or electronic timer circuit to control this duration.

Proper heat dissipation is necessary to prolong the life of the device. If the components of the device are housed in a container, it could be vented passively or with a fan. Proper heat sinks should be supplied to the voltage regulators and ballast resistors.

As a tool for light-curing, the currently described device differs from the handheld curing units which employ LEDs because the handheld units use a cluster of LEDs directed toward a fiber optic bundle, which transmits the light into the oral cavity when used in clinical practice. The currently described device has the LEDs arranged so that the light they emit directly impinges upon the surface of the body of the material to be cured, or upon a clear glass or plastic container filled with material to be cured. It can irradiate the entire surface of a body that is significantly larger than the 4-8 mm spot size of handheld light-curing guns.

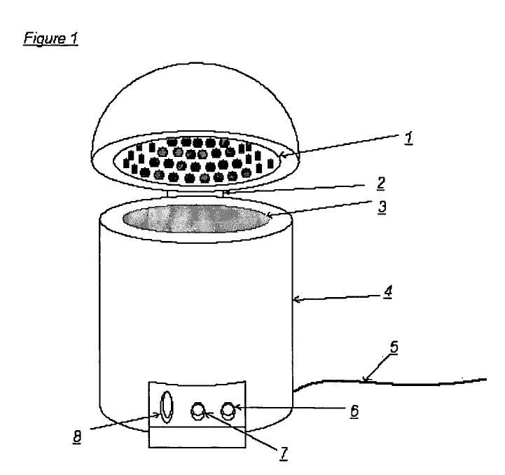

The currently described device may also be a light box that accommodates dentures, palettes, bridges, crowns, inlays or other prosthodontic appliances that require photo-initiation during their preparation. As shown in FIG. 1, dome-shaped chamber 1 has its interior surface wholly or partially covered with light-emitting diodes so that their light energy is directed toward a central region, which may have a platform 3 on which to place the appliance to be cured. In one embodiment, a hemispherical plastic shell having a diameter of 125 mm acts as a support frame for 200 blue-light-emitting diodes aimed roughly at the center of the hemisphere. This size provides ample clearance for the curing of polymer dental crowns, bridges and dentures. The LED-lined hemisphere is mounted on a hinge 2 that is attached to a base having a reflective flat surface that forms the flat lower boundary of the curing chamber. The base is a container 4 that houses the power supply, timing and intensity control circuits. It could also contain a switch that is closed when the LED-lined hemisphere is in the closed position. This switch acts as a safety interlock to avoid exposure of the operator to the bright blue light emitted when the device is turned on. Further components include a power cord 5, an intensity control 6, an illumination duration control 7 and a power switch 8.

Another embodiment of the proposed technology is an array of LEDs configured over a flat surface that are arranged so that their light energy is directed away from that surface. A flat object to be cured could be placed in front of this array, or a conveyor belt could pass in front of this array to cure objects placed on the belt.

### EXAMPLE #1

A comparison of the flexural modulus of bars cured using a filtered halogen light and those cured with an array of blue LED diodes was made. A light-curable polymer composite was prepared having a resin phase of 49.5 wt % urethane dimethacrylate and 49.5 wt % triethyleneglycol dimethacrylate to which 0/5 wt % of camphorquinone and 0.5 wt % dimethylaminoethyl methacrylate was added. To this resin was added at the 65 wt % level barium silicate glass particles (ave size=0.5 microns) having a functional silane treatment. The composite was injected into 25 mm lengths of glass tubing having an inside dimension of 2 mm square. They were light cured with overlapping 20 second applications of a hand-held halogen light curing source (Bluedent). Other bars were prepared using a LED light-curing device having four rows of nine blue LEDs arranged so that the rows directly faced the four long surfaces of the bar specimen. One 20 second light exposure was applied. Five bars prepared by each of the two curing methods were bent to fracture on a 20 mm span in three-point loading at 5 mm/min. The LED-cured bars possessed the same flexural modulus as the one cured by the halogen light (Halogen=6.6+/−0.2 GPa, LED=6.5+/−0.2 GPa). The LED-cured bars possessed the same flexural strength as the halogen-cured bars (Halogen=118+/−12 MPa, LED=115+/−4 MPa).

1. A device that possesses an array of light-emitting diodes configured to distribute their emitted light energy over the major portion of the surface of a volume of material.

2. The device in claim #1 having an array that is mounted on the interior surface of a hemisphere, cylinder or rectilinear box.
